(19) United States
(12) Patent Application Publication
(10) Pub. No.: US 2021/0385117 A1
(43) Pub. Date: Dec. 9, 2021

(54) Quickly Identifying RF Signals of Interest in RF Data Recordings

(71) Applicant: ERISYS LLC, Warrensburg, MO (US)

(72) Inventors: David E. ERISMAN, Herndon, VA (US); Donald William Metzger, Colorado Springs, CO (US)

(21) Appl. No.: 17/339,031

(22) Filed: Jun. 4, 2021

Related U.S. Application Data
(60) Provisional application No. 63/035,364, filed on Jun. 5, 2020.

(51) Int. Cl. H04L 27/26; G06F 17/14

(52) U.S. Cl. CPC H04L 27/2651; G06F 17/142

(57) ABSTRACT

Analysis of signal spectrum within a defined time period is performed by storing a signal sample, providing a displayable representation of the signal, and providing a detailed representation or analysis of a portion of the signal sample. An electromagnetic signal is received and corresponding data is stored. A signature characteristic of the signal is identified by examining general file characteristics, such as RF data and header file information. Time and frequency characteristics of the signal are determined and digital I/Q signal data are processed. A selection of a portion of the received electromagnetic field is identified and vector signal processing is applied to create a second set of similar plots, corresponding to the identified selected portion to provide simultaneous display in two display windows, with the second display window displaying the identified selected portion.

### RELATED APPLICATION

The present patent application claims priority to Provisional Patent Application No. 63/035,364 filed Jun. 5, 2020, which is assigned to the assignee hereof and filed by the inventors hereof and which is incorporated by reference herein.

### BACKGROUND

### Technical Field

The present invention relates to RF wideband spectrum capture systems and analysis tools. More specifically the invention relates to sharing RF spectrum recordings among multiple users.

### Background Art

RF signals are omnipresent, with sources including radio stations, cell phones, microwave links, satellite downlinks, and many other electronic devices. In many cases, the radiated electromagnetic waves need to be monitored for safety, interference, or other purposes. Specialized test equipment such as spectrum analyzers have been developed for the purpose of “seeing” these otherwise invisible signals. More recently RF spectrum data recorders have been developed that can digitize and store the RF spectrum information so that it can later be analyzed in great detail. The resulting data files can be extremely large when observing large swaths of the spectrum, and as a result, detailed analysis to find the signals of interest can take an exceedingly long time. As an example, an RF spectrum recorder looking at 1 GHz of spectrum must digitally sample the RF signals at over a billion times a second. Each sample typically requires 4 Bytes/sample which means a spectrum recording of 60 seconds will require a file size of 250 GB, or 1 TByte for every 4 minutes. Someone who wants to find a certain signal in such a large file would be faced with spending many hours searching the recording for their desired signal.

Long term analysis of RF signals that are present in the electromagnetic spectrum is currently done by digitally sampling portions of the RF spectrum, extracting the underlying modulation information into In-phase and Quadrature (I/Q) samples, storing the I/Q samples in large computer files, and then processing the I/Q samples using Fast Fourier Transforms (FFTs) that transform the time domain I/Q samples into frequency domain values that can be displayed on a computer screen or viewed visually. This process produces exceptionally large files since recording even one second's worth of spectral information can require many MBytes of underlying I/Q samples to be stored. To perform spectral analysis of 60 seconds of recorded I/Q data equating to many GBytes, currently available spectral analysis tools are not capable of providing insight into what signals are in the recording and where they are located.

It is desirable to reduce the bandwidth for analysis while maintaining a meaningful analysis, and to provide a means for communicating data for such analysis at reduced bandwidth.

By way of non-limiting example, to capture a portion of the RF spectrum that is 40 MHz wide (40 MHz bandwidth), a typical high performance system would need to store and process a minimum of 50 Msps (4 Bytes per sample) which translates to a requirement to continuously process and stream 200 MBytes of data per second to digital storage. For capturing 1000 MHz of bandwidth, the requirement would be to continuously process and stream 5000 MBytes of data per second to digital storage (1250 Msps×4 Bytes per sample). As bandwidths increase and observation times become longer, processor requirements and data throughput requirements become more challenging. If multiple RF spectrum monitors are deployed over a network to be monitored by a central command center, the throughput capacity of the network communications channel could quickly become overwhelmed by the size of the files needed to convey the underlying RF spectrum details.

### SUMMARY

Analysis of signal spectrum within a defined time period is performed by storing a signal sample, providing a displayable representation of the signal, and providing a detailed representation or analysis of a portion of the signal sample. An electromagnetic signal is received and corresponding data is stored. A signature characteristic of the signal is identified by examining general file characteristics, such as RF data and header file information. Time and frequency characteristics of the signal are determined and digital I/Q signal data are processed. A selection of a portion of the received signal is identified and vector signal processing is applied to create a second set of similar plots, corresponding to the identified selected portion to provide simultaneous display in two display windows, with the second display window displaying the identified selected portion.

In one particular configuration, the processing digital I/Q signal data comprises processing digital I/Q signal data by performing fast Fourier transforms (FFTs), storing the FFTs and associating the FFTs with the time and frequency characteristics of the signal to process and store FFT summary values for peak and average power as FFT summary files, and storing the FFT summary values. The stored FFT summary values are processed to plot RF power, RF frequency with persistence, and a spectrogram to provide a first visual image corresponding to segments of the I/Q signal data.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a spectrographic display showing a compressed bitmap image file that contains the summarized spectral information of the disclosed technique.

FIG. 2 is a spectrographic display showing a signal behavior that was flagged for further analysis.

FIGS. 3A-3C are spectrographic displays showing linked representations of a recorded file for an entire time period and a detailed analysis of a selected segment of the recorded file. FIG. 3A shows a view of linked representations of a recorded file for an entire time period. FIG. 3B shows a detailed analysis of a selected segment of the recorded file (FIG. 3B). FIG. 3C shows an example computer display interface showing simultaneous displays in a single display window.

FIG. 4 is a spectrographic display showing a close-up of the zoomed-out view of the complete recording, including a region defining time domain of interest.

FIG. 5 is a spectrographic display showing a close-up view showing a zoomed-in view of previously selected signal behavior.

FIG. 6 is a spectrographic display showing the results of further zooming-in from the displays of FIGS. 4 and 5.

FIG. 7 is a spectrographic display showing spectral event images.

FIG. 8 is a flow diagrams showing spectrum summary processing.

FIG. 9 is a flow diagram showing power summary processing.

### DETAILED DESCRIPTION

Overview

An RF wideband spectrum tool is used to capture and analyze electromagnetic signals, such as RF signals. The technique allows sharing RF spectrum recordings among multiple users who may be widely separated by distance and limited by low data transmission speeds. The technique allows these users to rapidly find RF signals of interest even in large RF spectrum recordings that may consist of many trillions of Bytes (TBytes) of I/Q data. The approach is to quickly find the desired RF signals by looking at specially created spectrum images that summarize the RF spectral events into larger time bins, thereby compressing the overall file size by orders of magnitude.

As a non-limiting example, every thousand or ten thousand samples can be summarized in a companion file and image. The companion file would then be thousands of times smaller without losing the important spectral information. This process allows a person to quickly visualize where their desired signals are located and then only use the time-consuming detailed signal analysis where these signals reside in the larger recording.

This technique allows many users to share the large recorded files and simultaneously search for only the signals they are interested in. Each user receives visual bitmap summaries of the recording and then requests the I/Q subset of data needed for their detailed analysis drastically cutting back on the flow of data normally required.

To perform spectral analysis, recorded files are algorithmically processed to compress the files and produce concise summary views that convey the critical information. These summary views are thus compressed to a size which results in files that are hundreds of times smaller than the original recorded I/Q file.

A real-time spectrum analyzer can be used to view a portion of the RF spectrum in extreme detail in which every in-band signal is continuously observed. The signal output is down-converted and filtered in front of the digitizer to present only the slice of bandwidth that can be processed by the sampling rate of the digitization process. The results of the RF digital sampling can be processed and viewed on a monitor screen and simultaneously streamed to a digital recorder.

In order to fully characterize the selected portion of the spectrum, the observed signals are down-converted to remove the redundancy of the RF carrier, and digitized to extract the underlying modulation information into I and Q orthogonal data pairs for each sample point interval. This sample point interval is determined by the width of the frequency band of interest. The stored I and Q digital samples are then processed using joint time-frequency analysis to create visualizations that provide insight into what RF signals are present and what their defining parameters are. The I and Q samples can be processed in a variety of ways to determine the details and parameters of all the signals contained within a desired RF bandwidth. As larger portions of the spectrum are sampled or when longer time durations are analyzed, the amount of data that needs to be stored, processed, and analyzed can quickly become the limiting factor in an RF spectrum analyzing system.

Each spectrum visualization requires the joint time-frequency processing of all the I and Q samples associated with the overall time of observance. For example, to create a spectrum image displaying 1000 MHz of bandwidth for a 10 second duration, a file size of 50 GBytes would need to be processed before the image could be viewed. If for example a signal of interest is only 1 MHz wide and one second long, the file size needed to process only this signal of interest could be reduced by orders of magnitude. In general, much of the data collected for continuously observing and monitoring RF spectrum is of little value and it is highly desirable to select and save the important data and discard the unneeded data in order to minimize data storage requirements.

The disclosed technique focuses on providing quicker access to actionable spectrum intelligence by drastically reducing the volume of information that must be transmitted over the network to convey the critical details. This process involves using FPGA and computer real-time processing to ingest large I/Q data files and then compute concise spectrum event images that contain the critical information. The spectrum events only require small file sizes of just a few hundred Kilobytes while still conveying the critical spectrum information. These spectrum event images can then be streamed using low bandwidth communication links. The spectrum events can be used to select only the necessary I/Q data sets needed for detailed vector signal analysis or can be stored into a database for further comparison, documentation, and report generation. The spectrum event images created with this process can be reduced in file size by a factor or 20,000:1 or more.

Technique

The disclosed technique is implemented by examining recorded RF data and header file data to determine general file parameters, such as the size of the file, an A/D sampling rate, the center frequency, and other key parameters. A determination is made of the time and frequency granularity settings suitable for summarizing this data.

The digital I/Q data is then processed by performing FFTs continuously using automated signal processing techniques. Non-limiting examples of such automated signal processing techniques include using high-speed FPGA, GPU, or multi-core computer processors. Using time/frequency granularity settings, FFT summary values for peak power and average power are processed and stored into a condensed pwrsum file, and FFT summary values for max hold spectral data are processed and stored into a condensed specsum file.

Output pwrsum and specsum files are produced by the processing of the digital I/Q data. The output pwrsum and specsum files are used to plot RF power, RF frequency with persistence. This data is used to generate a spectrogram using color lookup tables to provide a zoomed-out visual image of much larger segments of I/Q data than can be displayed by conventional vector signal processing.

Elapsed time is monitored by tracking memory sample addresses for both the original I/Q recording and the condensed summary files. Simultaneous use of conventional vector signal processing is used to create a second set of similar plots in an adjacent display window. The two display windows are time synchronized so that inputs on one window can interact precisely with the data displayed on the other window. The summarized zoomed-out display is utilized as a macro view of long duration RF spectral activity. The zoomed out spectral display is converted into very small .png or other image format files that maintain time synchronization hooks to the recorded I/Q file.

For remote access or multi-user distribution, the compressed spectral image files may be transmitted to other remote users. Since the image files are compressed, the files can be conveniently transmitted to remote users hindered by low data rate connections.

The data can then be analyzed to recognize spectral events worthy of further analysis based on the visual images in the highly compressed .png files and segment blocks containing the desired spectral images can be selected. Human analysis can be used; however, this process can be automated using machine learning, based on prior results, for automated recognition of file patterns which can be used to automatically select segment blocks containing the desired spectral images.

The selected segment blocks of the zoomed out .png files are converted and stored into the memory locations of the corresponding I/Q values in the recorded RF data. This allows transmission of only a minimum amount of I/Q data necessary. The extracted data can nevertheless be processed in extreme detail by conventional vector signal analysis to uncover the modulation characteristics needed to identify the critical signals of interest. The identification can be automated so that machine learning can be used to provide the identification based on prior results, in which automated recognition of file patterns which can be used to automatically select segment blocks containing the desired spectral images.

The use of .png files is given as a non-limiting example, as any suitable compressed file providing detailed information can be used.

### Example

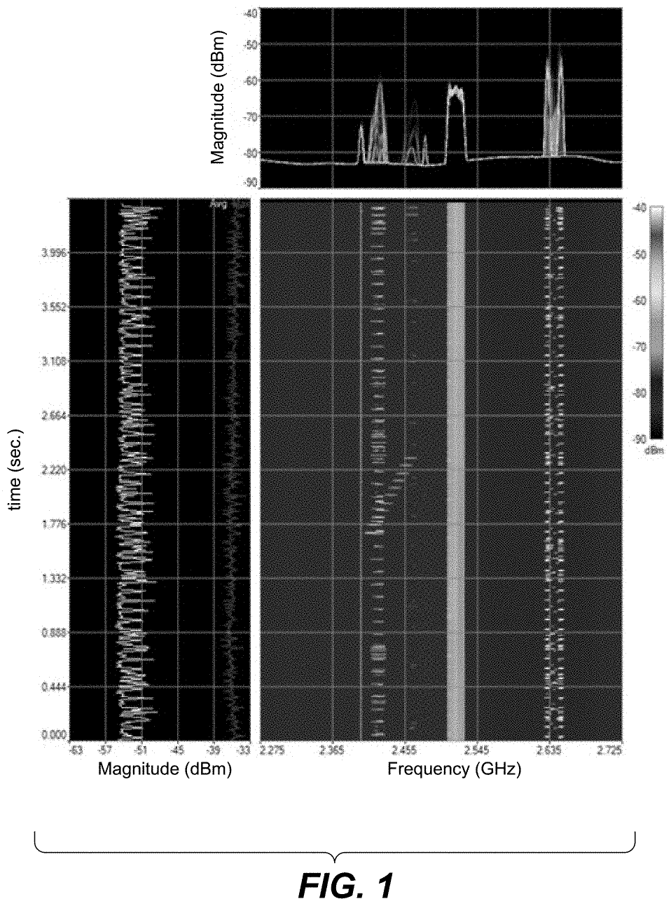

FIG. 1 is a spectrographic display showing the 200 KByte compressed bitmap image file that contains the summarized spectral information of the disclosed technique. In this non-limiting example, the recording duration processed was 4.5 seconds using a 450 MHz span centered at 2.455 MHz which requires an I/Q file size of 9.7 GB. By using the disclosed technique to summarize the large I/Q file, the small bitmap image can be easily accessed over low bandwidth data links and used to determine if there are signals of further interest.

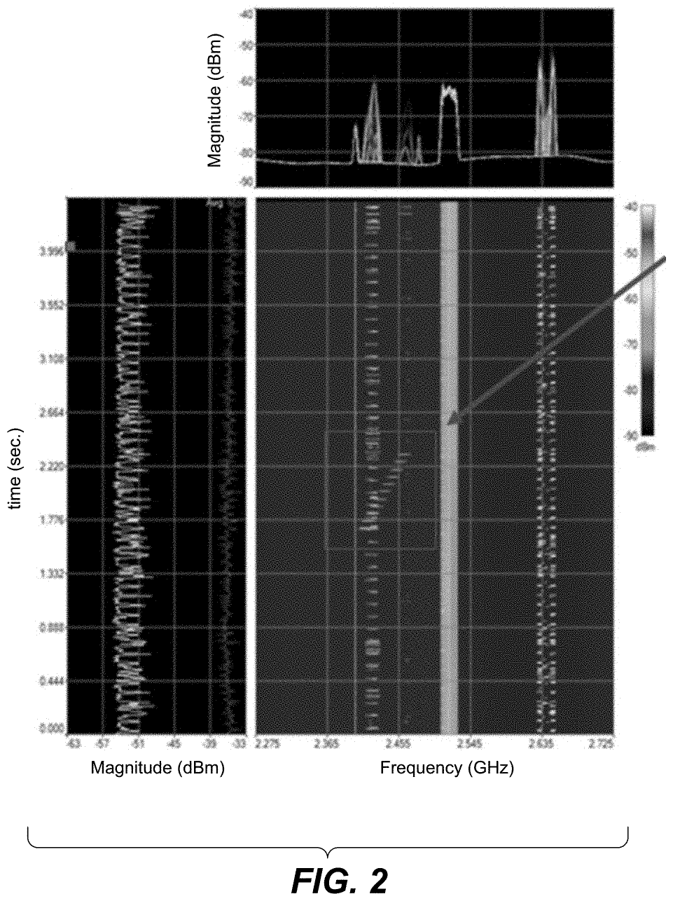

FIG. 2 is a spectrographic display showing a signal behavior that was flagged for further analysis. An analyst looking at the image, or algorithm programmed to examine and automatically analyze the image, would be able to draw a box around the signal of interest and automatically request the I/Q data necessary for detailed analysis of the selected waveform. If deemed important, only the small amount of relevant I/Q data would need to be saved to disk and the waveform could later be used as a “fingerprint” to identify this type of emitter. As is the case shown in FIG. 1, the spectrum event image pictured shows a real-time span of 450 MHz observed for about 4.5 seconds. In one non-limiting example, the underlying I/Q samples equate to a file size of around 10 GBytes which is reduced to less than 200 KBytes once the spectrum event image is created, a 50,000:1 reduction in size.

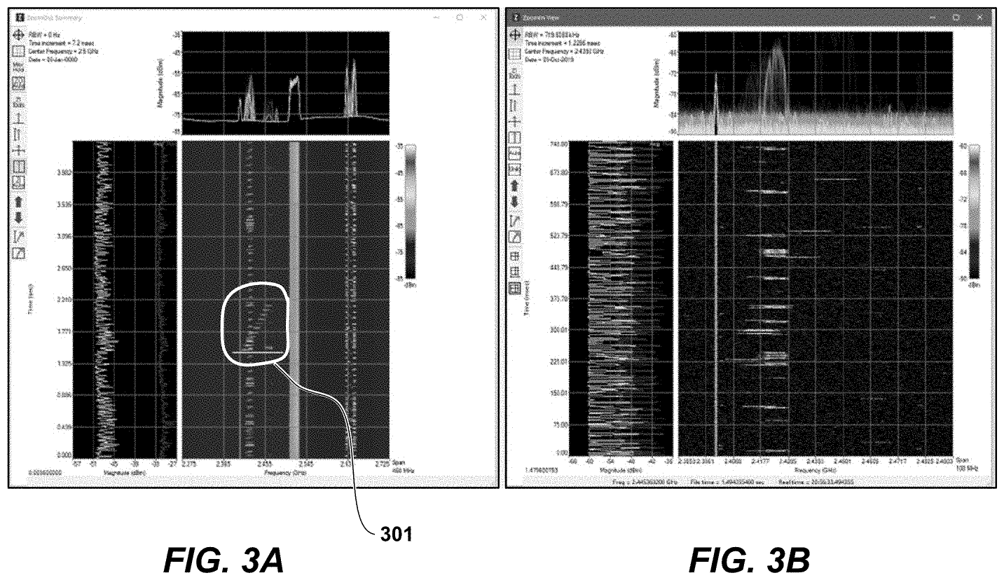

FIGS. 3A-3C are spectrographic displays showing linked representations of a recorded file for an entire time period and a detailed analysis of a selected segment of the recorded file. FIGS. 3A and 3B show a view of linked representations of a recorded file for an entire time period (FIG. 3A) and a detailed analysis of a selected segment of the recorded file (FIG. 3B). These displays are suitable for simultaneous display on a single computer display, but can also be provided as separate displays, for example, from a single monitor or two monitors which may be driven by one computer. FIG. 3C shows an example computer display interface showing simultaneous displays in a single display window. FIG. 3A shows the macro view of an entire 4.5 seconds (as a non-limiting example) of a recorded file while the zoomed-in image is shown in FIG. 3B. FIG. 3B shows only 480 msec (also as a non-limiting example) of selected spectrum that has been chosen for more detailed analysis. FIGS. 3A and 3B correspond to the left and right sides of the display window FIG. 3C.

In FIG. 3A, a selection is made, identified by the wide horizontal lines in area 301 at the top and bottom of area 301. The selection contains a series of spurious signals appearing as approximately eleven small horizontal lines. The horizontal lines define a time domain of interest, which will be further analyzed, for zooming in to the spectrograph for further analysis using a computer interface such as the computer interface menu of FIG. 3C. This time domain of interest is displayed in the segment of FIG. 3B which shows details of the time domain of interest.

Area of interest 301 is expanded in FIG. 3B. In this particular example, the eleven horizontal lines do not appear to contain significant intelligence and, depending on the purpose of the analysis, can be regarded as background noise, or warrant further investigation.

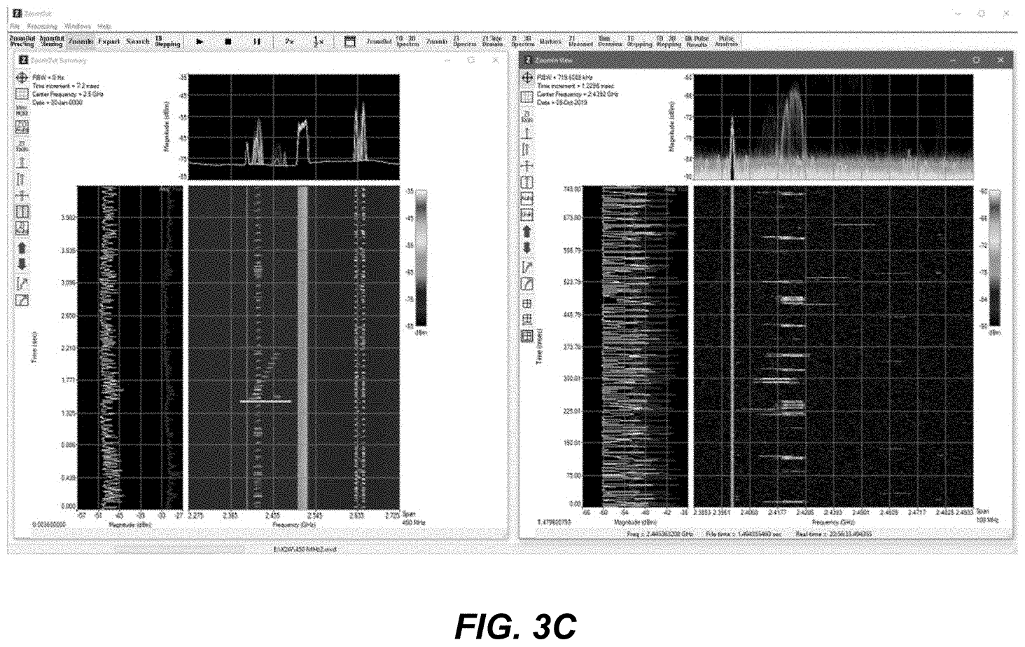

FIG. 4 is a spectrographic display showing a close-up of the zoomed-out view of the complete recording with the broad horizontal lines on the display (displayed as red and white horizontal lines), defining time domain of interest 301. The horizontal lines show the start and stop points respectively of the zoomed-in analysis window. The broad horizontal lines defining time domain of interest 301 will automatically follow the zoomed-in window settings so that users can always see what segment of the full file is currently being examined.

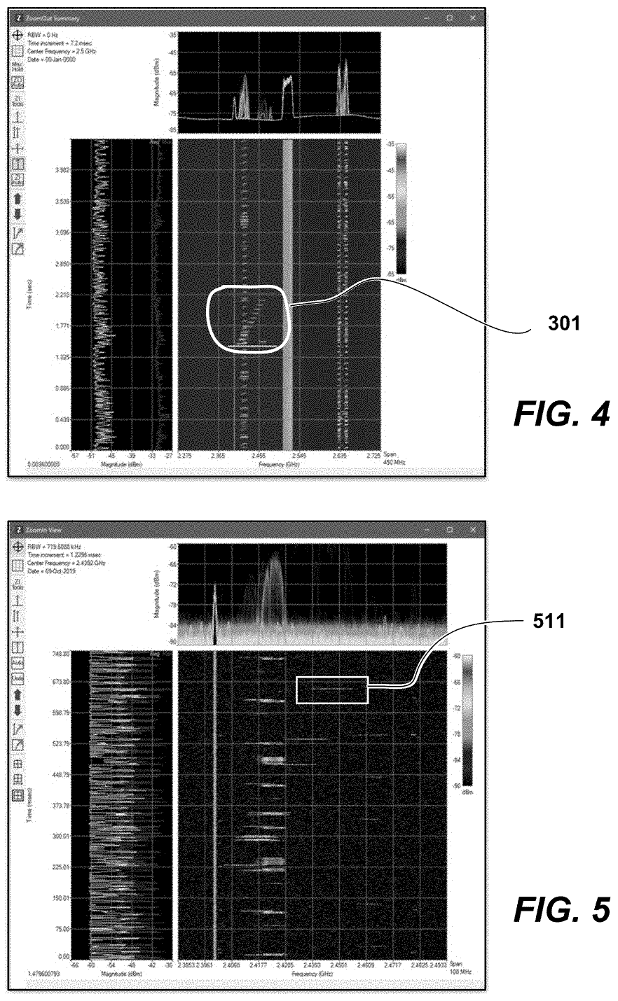

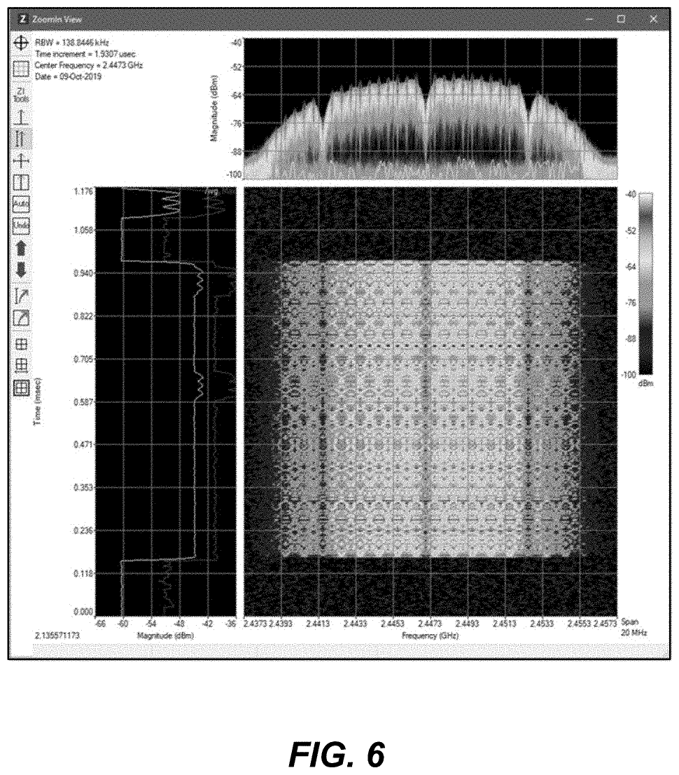

FIG. 5 is a spectrographic display showing a close-up view showing 748 msec of the zoomed-in view of the previously selected signal behavior. By selecting an even smaller section of the spectrum by enclosing the desired signal within selection box 511, even more detail can automatically be brought into view as shown in FIG. 6.

FIG. 6 is a spectrographic display showing the results of further zooming-in on just the 1.18 msec identified by the selection box 511 shown in FIG. 5. Now the details of the signal of interest can be seen and analyzed. Image recognition, I/Q waveform audio playback, and machine learning can be utilized for automated searching and identification operations.

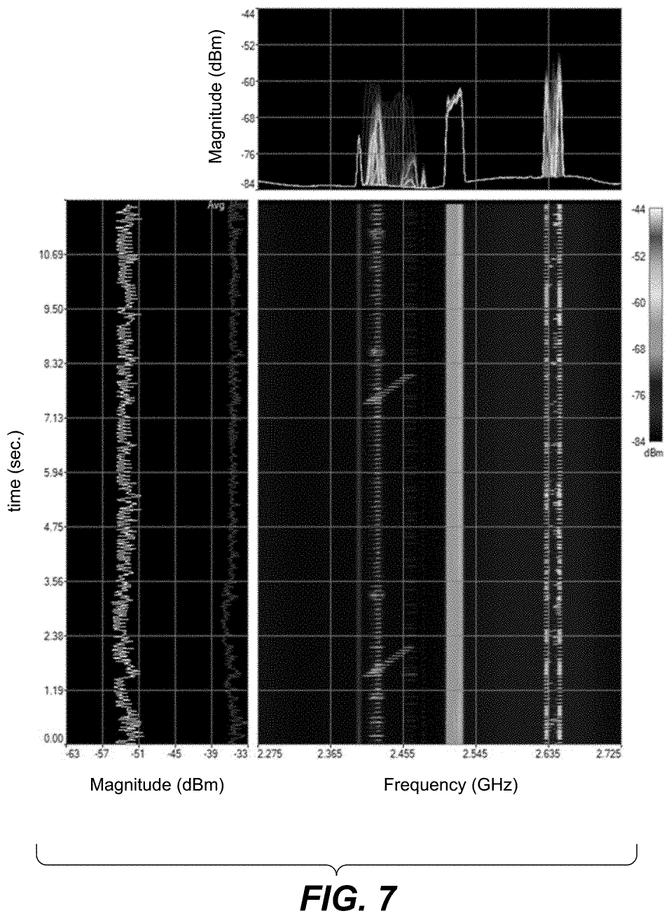

FIG. 7 is a spectrographic display showing spectral event images. The spectral event image shown on the lower part of the image presents the observer with 15 seconds of elapsed time in one image that can be stored in a file containing about 200 KBytes of data but which retains the synchronizing links to the underlying I/Q file which requires 25.95 GBytes of data memory. By compressing the I/Q information with the disclosed technique, the long-term signal characteristics can be observed and then selected I/Q spectral events can be imported even over a low speed network into a separate display window for further detailed analysis.

Process Flow

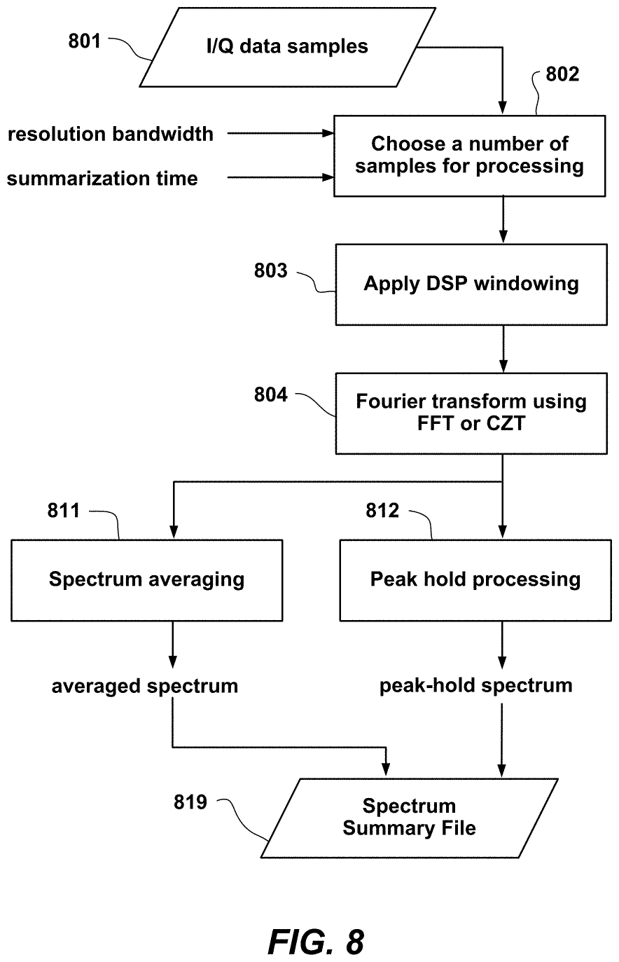

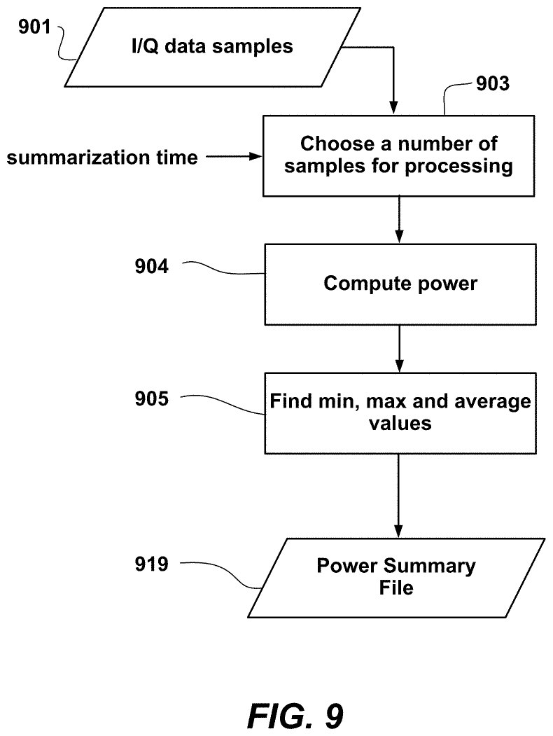

FIGS. 8 and 9 are flow diagrams showing spectrum summary processing (FIG. 8) and power summary processing (FIG. 9).

Referring to FIG. 8, for spectrum summary processing I/Q data, samples are received (step 801), and a number of samples are taken (step 802), based on a desired resolution bandwidth and summation time. The number of samples is applied for digital signal processing (DSP) windowing (step 803). A Fourier transform is performed (step 804), for example by use of a fast Fourier transform (FFT), by Chirp-Z Transform (CZT) techniques or other signal detection. The Fourier output is processed using spectrum averaging (step 811) and peak-hold processing (step 812), to provide an averaged spectrum output or peak-hold spectrum output, respectively. The averaged spectrum peak-hold spectrum outputs are provided in a spectrum summary file (step 819).

Referring to FIG. 9, for power summary processing I/Q data, samples are received (step 901), and samples are taken (step 903), but since the data of interest is power, the summary I/Q data samples are taken based on a summation time, but without the resolution bandwidth used for spectrum summary processing. Power is computed (step 904), and the computed power is used to find minimum, maximum or peak power and average power values (step 905). The averaged power peak-hold power values are used as outputs provided in a power summary file (step 919).

Closing Statement

It will be understood that many additional changes in the details, steps, algorithms and display and processing configurations, which have been herein described and illustrated to explain the nature of the subject matter, may be made by those skilled in the art within the principle and scope of the invention as expressed in the appended claims.

What is claimed is:

1. A method for determining a category or general characteristic of an electromagnetic signal, the method comprising:
receiving or sampling the electromagnetic signal and storing a representation of the received or sampled electromagnetic signal as electromagnetic signal data;
identifying a signature characteristic of the electromagnetic signal, the identifying comprising:
examining general file characteristics comprising information comprising radio frequency (RF) data and header file information,
determining time and frequency characteristics of the signal, and
processing digital I/Q signal data;
receiving or identifying a selection of a portion of the received or sampled electromagnetic field data, as an identified selected portion;
applying vector signal processing to create a second set of similar plots, corresponding to the identified selected portion, to provide at least two display windows, with the second display window displaying the identified selected portion; and
time synchronizing the two display windows so that inputs on first visual image correlate with the data displayed on the second display window.

2. The method of claim 1, wherein the processing digital I/Q signal data comprises:
processing digital I/Q signal data by performing fast Fourier transforms (FFTs),
storing the FFTs and associating the FFTs with the time and frequency characteristics of the signal to process and store FFT summary values for peak and average power as FFT summary files, and storing the FFT summary values, and
processing the stored FFT summary values to plot RF power, RF frequency with persistence, and spectrogram using lookup tables to provide a first visual image corresponding to segments of the I/Q signal data.

3. The method of claim 2, wherein the examining the general file characteristics comprises examining key signal parameters from recorded RF data and header file data selected from the group consisting of file size, an analog-to-digital (A/D) sampling rate and a center frequency.

4. The method of claim 2, further comprising:
examining key signal parameters from recorded RF data and header file data selected from the group consisting of file size, an analog-to-digital (A/D) sampling rate and a center frequency, and using the key signal parameters as the general file characteristics; and
converting the selected segment blocks to display of the corresponding I/Q signal values; and
processing process the data by vector signal analysis to uncover the modulation characteristics to identify signals of interest.

5. The method of claim 2, further comprising:
examining key signal parameters from recorded RF data and header file data selected from the group consisting of file size, an analog-to-digital (A/D) sampling rate and a center frequency, and using the key signal parameters as the general file characteristics; and
converting the selected segment blocks to display of the corresponding I/Q signal values; and
processing process the data by vector signal analysis to uncover the modulation characteristics to identify signals of interest, using machine learning.

6. The method of claim 2, further comprising:
using a summarized display to provide a macro view of long duration of RF spectral activity; and
converting the summarized display into a reduced size image format file that maintains the time and frequency characteristics of the signal represented by the two display windows.

7. The method of claim 2, further comprising:
transmitting, for remote access or multi-user distribution, compressed spectral image files to remote users, thereby supporting transmission through low data rate connections.

8. The method of claim 2, further comprising:
transmitting, for remote access or multi-user distribution, compressed spectral image files to remote users;
applying machine learning to recognize spectral events for further analysis based on the visual images in the compressed spectral image files; and
automatically selecting segment blocks for review.

9. The method of claim 2, further comprising:
converting the selected segment blocks of the zoomed out png files into the memory locations of the corresponding I/Q values in the recorded RF data, transmit only the minimum amount of I/Q data necessary, and process the extracted data in extreme detail by conventional vector signal analysis to uncover the modulation characteristics needed to identify the critical signals of interest either by machine learning techniques or manually.

10. The method of claim 1, wherein the processing digital I/Q signal data comprises:
extracting power and frequency characteristics of the electromagnetic signal;
scanning the power and frequency characteristics for predetermined parameters; and
identifying one or more blocks of the stored representation exhibiting the predetermined parameters.

11. The method of claim 1, wherein the examining the general file characteristics comprises examining key signal parameters from recorded RF data and header file data selected from the group consisting of file size, an analog-to-digital (A/D) sampling rate and a center frequency.

12. The method of claim 1, further comprising:
using a summarized display to provide a macro view of long duration of RF spectral activity; and
converting the summarized display into a reduced size image format file that maintains the time and frequency characteristics of the signal represented by the two display windows.

13. The method of claim 1, further comprising:
transmitting, for remote access or multi-user distribution, compressed spectral image files to remote users, thereby supporting transmission through low data rate connections.

14. The method of claim 1, further comprising:
transmitting, for remote access or multi-user distribution, compressed spectral image files to remote users;
applying machine learning to recognize spectral events for further analysis based on the visual images in the compressed spectral image files; and
automatically selecting segment blocks for review.

15. A computer program product, comprising:
a non-transitory computer-readable medium comprising:
a first instruction for causing a computer to
receive or sample an electromagnetic signal as electromagnetic signal data;
identify a signature characteristic of the electromagnetic signal, the identifying comprising:
examine general file characteristics comprising information comprising radio frequency (RF) data and header file information;
determine time and frequency characteristics of the signal;
process digital I/Q signal data;
receive or identify a selection of a portion of the received or sampled electromagnetic field data, as an identified selected portion;
apply vector signal processing to create a second set of similar plots, corresponding to the identified selected portion, to provide at least two display windows, with the second display window displaying the identified selected portion; and
time synchronizing the two display windows so that inputs on first visual image correlate with the data displayed on the second display window.

16. The computer program product of claim 15, wherein the processing digital I/Q signal data comprises:
processing digital I/Q signal data by performing fast Fourier transforms (FFTs),
storing the FFTs and associating the FFTs with the time and frequency characteristics of the signal to process and store FFT summary values for peak and average power as FFT summary files, and storing the FFT summary values, and
processing the stored FFT summary values to plot RF power, RF frequency with persistence, and spectrogram using lookup tables to provide a first visual image corresponding to segments of the I/Q signal data.

17. The computer program product of claim 15, wherein the processing digital I/Q signal data comprises:
extracting power and frequency characteristics of the electromagnetic signal;
scanning the power and frequency characteristics for predetermined parameters; and
identifying one or more blocks of the stored representation exhibiting the predetermined parameters.

18. A method for determining a category or general characteristic of an electromagnetic signal, the method comprising:
a step of receiving or sampling the electromagnetic signal;
a step of identifying a signature characteristic of the electromagnetic signal, the identifying comprising:
examining general file characteristics comprising information comprising radio frequency (RF) data and header file information,
determining time and frequency characteristics of the signal, and
processing digital I/Q signal data;
a step of receiving or identifying a selection of a portion of the received or sampled electromagnetic field, as an identified selected portion;
a step of applying vector signal processing to create a second set of similar plots, corresponding to the identified selected portion, to provide at least two display windows, with the second display window displaying the identified selected portion; and
a step of time synchronizing the two display windows so that inputs on first visual image correlate with the data displayed on the second display window.

19. The method of claim 18, wherein the processing digital I/Q signal data comprises:
processing digital I/Q signal data by performing fast Fourier transforms (FFTs),
storing the FFTs and associating the FFTs with the time and frequency characteristics of the signal to process and store FFT summary values for peak and average power as FFT summary files, and storing the FFT summary values, and
processing the stored FFT summary values to plot RF power, RF frequency with persistence, and spectrogram using lookup tables to provide a first visual image corresponding to segments of the I/Q signal data.
